(19) United States
(12) Patent Application Publication
(10) Pub. No.: US 2007/0155064 A1
(43) Pub. Date: Jul. 5, 2007

(54) Method for manufacturing carbon nano-tube FET

(75) Inventors: Bae-Horng Chen, Taoyuan County (TW); Jeng-Hua Wei, Taipei City (TW); Po-Yuan Lo, Taipei City (TW); Zing-Way Pei, Taichung City (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/430,938

(22) Filed: May 10, 2006

(30) Foreign Application Priority Data
Dec. 29, 2005 (TW) 094147140

(51) Int. Cl. H01L 21/8232; H01L 21/335

(52) U.S. Cl. 438/142

(57) ABSTRACT

A method for manufacturing a carbon nano-tube field-effect transistor (CNT-FET), comprising steps of: forming a patterned conductive layer on a substrate; forming a dielectric layer covering the conductive layer and the substrate; forming a carbon nano-tube layer between a pair of electrodes on the dielectric layer; and performing a treatment process on the carbon nano-tube layer so that the carbon nano-tube layer is semiconducting.

### BACKGROUND OF THE INVENTION

1. Field of the Invention

The present invention generally relates to a method for manufacturing a carbon nano-tube field-effect transistor (CNT-FET) and, more particularly, to a method using a treatment process after carbon nano-tubes are deposited so as to convert metallic carbon nano-tubes into semiconducting carbon nano-tubes.

2. Description of the Prior Art

Carbon nano-tubes (CNTs) have attracted lots of attention due to some important characteristics (such as flexibility, thermal conductivity, electrical conductivity, ability in light-emitting and self-assembly) that are advantageous over silicon. CNT-based materials exhibit different conducting types—metallic type and semiconducting type according to the effective chirality. Whatever the method for growing the CNT-based materials may be, any CNT-based material comprises both metallic carbon nano-tubes and semiconducting carbon nano-tubes.

The field-effect transistor (FET) has become the most important and widely used device in the electronic industry. However, a FET comprising metallic carbon nano-tubes in the channel exhibits poor ON/OFF switching characteristics. Therefore, it is the greatest challenge to obtain high-purity semiconducting carbon nano-tubes.

In Science, 292, 706 (2001), Collins et al demonstrate a method for selectively removing single carbon shells from multi-walled CNTs (MWNTs) stepwise and individually characterize the different shells using the partial electrical breakdown of a MWNT at constant voltage stress. By choosing among the shells, Collins et al convert a MWNT into either a metallic or a semiconducting conductor. This approach uses current-induced electrical breakdown to eliminate individual shells one at a time, and the outer shells are more likely to breakdown. However, the applied current requires to be controlled precisely, otherwise, both metallic and semiconducting CNTs would fail. Moreover, this method is time-consuming.

In Nano Letters, 4, 827 (2004), Balasubramanian et al disclose a selective electrochemical approach to carbon nano-tube field-effect transistors. Balasubramanian et al uses electrochemistry for selective covalent modification of metallic nano-tubes, resulting in exclusive electrical transport through the unmodified semiconducting tubes. The semiconducting tubes are rendered nonconductive by application of an appropriate gate voltage prior to the electrochemical modification. The FETs fabricated in this manner display good hole mobilities and a ratio approaching 106 between the current in the ON and OFF states. However, this approach is problematic. For example, when there are much more metallic nano-tubes than semiconducting nano-tubes in the deposited CNT-based material, this electrochemical approach can only improve the electrical characteristics of the few semiconducting CNT-FETs and still fails to increase the percentage of semiconducting CNT-FETs. On the other hand, this approach requires the chip to be immersed in the chemical solution, which reduces the yield and throughput. Moreover, the phenyl group in the solution may react with semiconducting CNTs to form covalent bonds and adversely affects the electrical characteristics of the chip, which makes it unsuitable for use in sensors.

Therefore, there exists a need in providing a method for manufacturing a carbon nano-tube field-effect transistor using a treatment process after carbon nano-tubes are deposited so as to convert metallic carbon nano-tubes into semiconducting carbon nano-tubes suitable for use in FETs, sensors, and organic transistors.

### SUMMARY OF THE INVENTION

It is a primary object of the present invention to provide a method for manufacturing a carbon nano-tube field-effect transistor using a treatment process after carbon nano-tubes are deposited so as to convert metallic carbon nano-tubes into semiconducting carbon nano-tubes suitable for use in FETs, sensors, and organic transistors.

It is another object of the present invention to provide a method for manufacturing a carbon nano-tube field-effect transistor using a treatment process after carbon nano-tubes are deposited so as to convert metallic carbon nano-tubes into semiconducting carbon nano-tubes to improve the reliability and enhance the throughput.

In order to achieve the foregoing objects, in a first embodiment, the present invention provides a method for manufacturing a carbon nano-tube field-effect transistor, the method comprising steps of: forming a patterned conductive layer on a substrate; forming a dielectric layer covering the conductive layer and the substrate; forming a carbon nano-tube layer between a pair of electrodes on the dielectric layer; and performing a treatment process on the carbon nano-tube layer so that the carbon nano-tube layer is semiconducting.

In a second embodiment, the present invention provides a method for manufacturing a carbon nano-tube field-effect transistor, the method comprising steps of: forming a patterned conductive layer on a substrate; forming a dielectric layer covering said conductive layer and said substrate; and forming an organic semiconductor layer between a pair of electrodes on said dielectric layer; wherein said organic semiconductor layer is doped with a plurality of semiconducting carbon nano-tube particles.

In a third embodiment, the present invention provides a method for manufacturing a carbon nano-tube field-effect transistor, the method comprising steps of: forming a patterned conductive layer on a substrate; forming a dielectric layer covering the conductive layer and the substrate; forming a carbon nano-tube layer between a pair of islands on the dielectric layer, the pair of islands comprising a catalyst; forming a pair of electrodes on the dielectric layer, the pair of electrodes covering the islands and being electrically coupled to the carbon nano-tube layer; and performing a treatment process on the carbon nano-tube layer so that the carbon nano-tube layer is semiconducting.

In a fourth embodiment, the present invention provides a method for. manufacturing a carbon nano-tube field-effect transistor, the method comprising steps of: forming a carbon nano-tube layer between a pair of electrodes on a substrate; performing a treatment process on the carbon nano-tube layer so that the carbon nano-tube layer is semiconducting; forming a dielectric layer on the carbon nano-tube layer and the pair of electrodes; and forming a patterned conductive layer.

In a fifth embodiment, the present invention provides a method for manufacturing a carbon nano-tube field-effect transistor, the method comprising steps of: forming an organic semiconductor layer between a pair of electrodes on a substrate; forming a dielectric layer on said organic semiconductor layer; and forming a patterned conductive layer on said dielectric layer; wherein said organic semiconductor layer is doped with a plurality of semiconducting carbon nano-tube particles.

In a sixth embodiment, the present invention provides a method for manufacturing a carbon nano-tube field-effect transistor, the method comprising steps of: forming a carbon nano-tube layer between a pair of islands on a substrate, said pair of islands comprising a catalyst; forming a pair of electrodes on the substrate, the pair of electrodes covering the islands and being electrically coupled to the carbon nano-tube layer; performing a treatment process on the carbon nano-tube layer so that the carbon nano-tube layer is semiconducting; forming a dielectric layer on the carbon nano-tube layer and the pair of electrodes; and forming a patterned conductive layer on the dielectric layer.

### BRIEF DESCRIPTION OF THE DRAWINGS

The objects, spirits and advantages of the preferred embodiments of the present invention will be readily understood by the accompanying drawings and detailed descriptions, wherein:

FIG. 1A to FIG. 1E are cross-sectional views showing a method for forming a carbon nano-tube field-effect transistor according to a first embodiment of the present invention;

FIG. 2A to FIG. 2C are cross-sectional views showing a method for forming a carbon nano-tube field-effect transistor according to a second embodiment of the present invention;

FIG. 3A to FIG. 3F are cross-sectional views showing a method for forming a carbon nano-tube field-effect transistor according to a third embodiment of the present invention;

FIG. 4A to FIG. 4D are cross-sectional views showing a method for forming a carbon nano-tube field-effect transistor according to a fourth embodiment of the present invention;

FIG. 5A to FIG. 5B are cross-sectional views showing a method for forming a carbon nano-tube field-effect transistor according to a fifth embodiment of the present invention; and

FIG. 6A to FIG. 6E are cross-sectional views showing a method for forming a carbon nano-tube field-effect transistor according to a sixth embodiment of the present invention.

### DETAILED DESCRIPTION OF THE PREFERRED EMBODIMENT

The present invention providing a method for manufacturing a carbon nano-tube field-effect transistor can be exemplified by the preferred embodiments as described here in after.

### First Embodiment

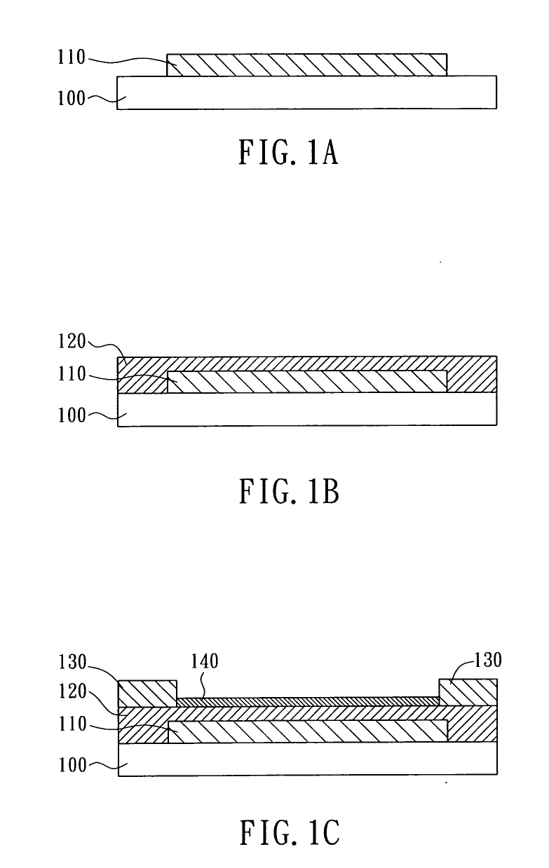

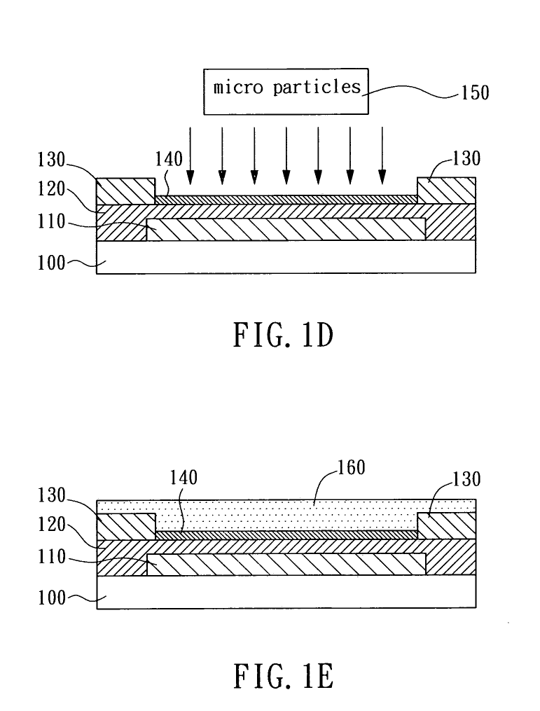

FIG. 1A to FIG. 1E are cross-sectional views showing a method for forming a carbon nano-tube field-effect transistor according to a first embodiment of the present invention. In FIG. 1A, a substrate 100 is provided, and a patterned conductive layer 110 is formed on the substrate 100. In the present embodiment, the substrate 100 can be a glass substrate, a flexible substrate or a conductive substrate with an insulating layer thereon. The patterned conductive layer 110 comprises metal, poly-silicon, conductive polymer or combination thereof. In general, the patterned conductive layer 110 is used as the bottom gate of a thin-film transistor.

In FIG. 1B, a dielectric layer 120 is then formed to cover the conductive layer 110 and the substrate 100. In the present embodiment, the dielectric layer 120 comprises oxide, nitride, insulating polymer or the combination thereof.

Then, a carbon nano-tube layer 140 between a pair of electrodes 130 is formed on the dielectric layer 120, as shown in FIG. 1C. In the present embodiment, the electrodes 130 comprise metal, conductive polymer or combination thereof. The carbon nano-tube layer 140 is formed using spin coating, ink-jet printing, screen-printing, thermal transfer printing or imprinting. In general, the electrodes 130 are used as the drain electrode and the source electrode. Part of the carbon nano-tube layer 140 is used as the channel layer.

A carbon nano-tube field-effect transistor has been completed using the afore-mentioned steps. However, the carbon nano-tube layer 140 usually comprises both metallic carbon nano-tubes and semiconducting carbon nano-tubes. Metallic carbon nano-tubes are not suitable for use in a channel for a field-effect transistor because a channel having metallic carbon nano-tubes may exhibit poor switching characteristics. Therefore, a treatment process is preferably performed on the carbon nano-tube layer 140 so as to convert metallic carbon nano-tubes into semiconducting carbon nano-tubes. In the present embodiment, the treatment process comprises one process selected from a group including a physical treatment process, a chemical treatment process and combination thereof. Preferably, the physical treatment process comprises a step of bombarding the carbon nano-tube layer with micro particles 150, as shown in FIG. 1D.

Preferably, the micro particles 150 are provided using one source selected from a group including a plasma generator, an ion implanter, an ion shower, and an electron gun. With the bombardment of the micro particles 150, the effective chirality of the carbon nano-tubes is altered, which convert the metallic carbon nano-tubes into semiconducting carbon nano-tubes. Alternatively, the physical treatment process comprises a step of inducing eddy currents in the carbon nano-tube layer 140 so as to burn up the metallic carbon nano-tubes and increase the semiconducting-to-metallic ratio. Preferably, the chemical treatment process comprises a step of providing reactive ions to react with the carbon nano-tube layer.

Preferably, in the present embodiment, the method further comprises a step of forming an organic semiconductor layer 160 covering the carbon nano-tube layer 140 and the pair of electrodes 130 after the treatment process so as to form an organic field-effect transistor, as shown in FIG. 1E. In the present embodiment, the organic semiconductor layer 160 is a polymeric material formed by spin coating, ink-jet printing, screen printing, thermal transfer printing or imprinting or a small molecular material formed by evaporation.

Preferably, a passivation layer (not shown) can be further provided on the organic semiconductor layer 160 so as to prevent the organic semiconductor layer 160 from moisture or oxide. The passivation layer can be implemented using oxide, nitride, insulating-polymer or the combination thereof.

### Second Embodiment

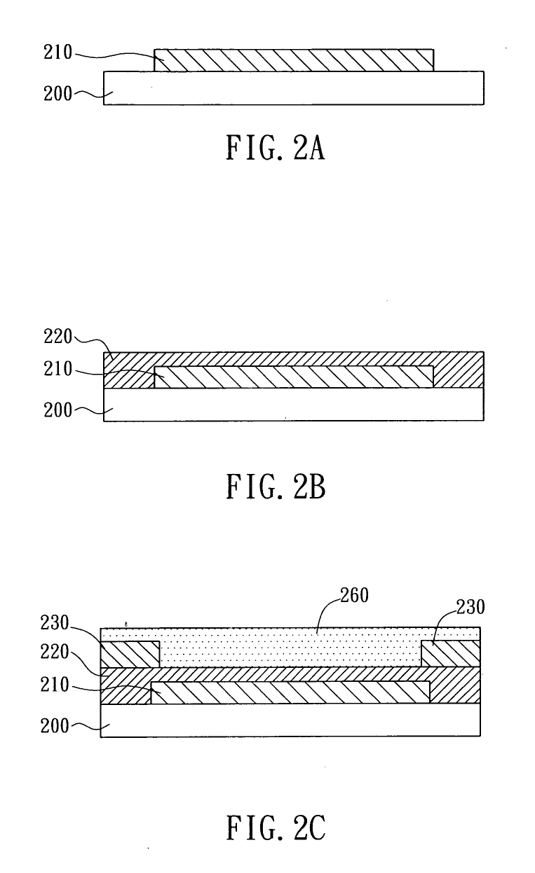

FIG. 2A to FIG. 2C are cross-sectional views showing a method for forming a carbon nano-tube field-effect transistor according to a second embodiment of the present invention. In FIG. 2A, a substrate 200 is provided, and a patterned conductive layer 210 is formed on the substrate 200. In the present embodiment, the substrate 200 can be a glass substrate, a flexible substrate or a conductive substrate with an insulating layer thereon. The patterned conductive layer 210 comprises metal, poly-silicon, conductive polymer or combination thereof. In general, the patterned conductive layer 210 is used as the bottom gate of a thin-film transistor.

In FIG. 2B, a dielectric layer 220 is then formed to cover the conductive layer 210 and the substrate 200. In the present embodiment, the dielectric layer 220 comprises oxide, nitride, insulating polymer or the combination thereof.

Then, an organic semiconductor layer 260 between a pair of electrodes 230 is formed on the dielectric layer 220, as shown in FIG. 2C, wherein the organic semiconductor layer 260 is doped with a plurality of semiconducting carbon nano-tube particles (not shown) so as to increase the electrical characteristics of an organic CNT field-effect transistor.

In the present embodiment, the electrodes 230 comprise metal, conductive polymer or combination thereof. In general, the electrodes 230 are used as the drain electrode and the source electrode. Part of the organic semiconductor layer 260 is used as the channel layer. In the present embodiment, the organic semiconductor layer 260 is a polymeric material formed by spin coating, ink-jet printing, screen printing, thermal transfer printing or imprinting or a small molecular material formed by evaporation.

Preferably, a passivation layer (not shown) can be further provided on the organic semiconductor layer 260 so as to prevent the organic semiconductor layer 260 from moisture or oxide. The passivation layer can be implemented using oxide, nitride, insulating polymer or the combination thereof.

### Third Embodiment

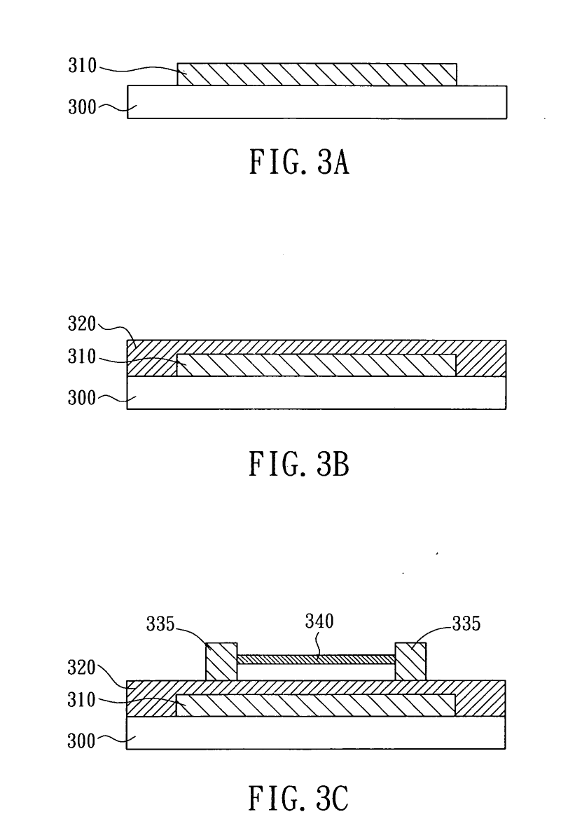

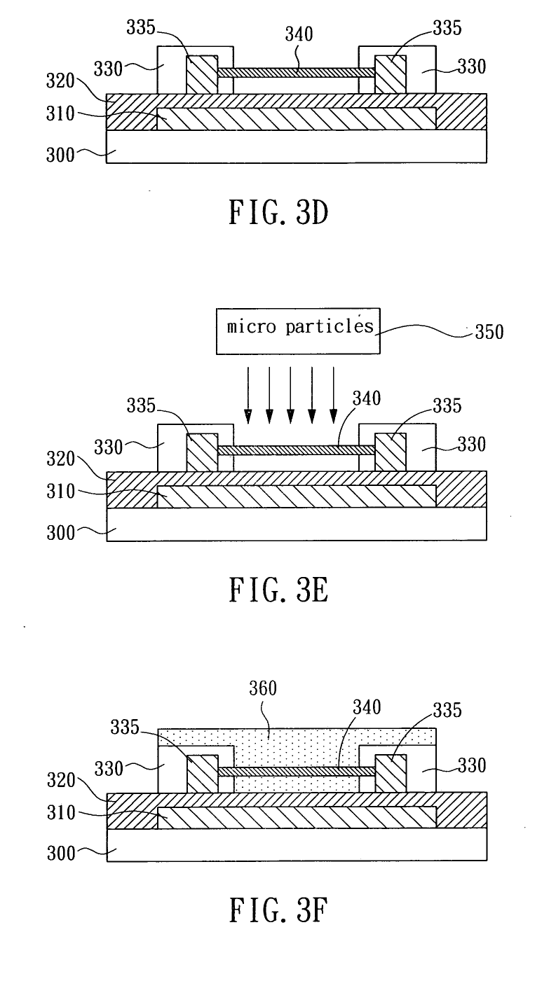

FIG. 3A to FIG. 3F are cross-sectional views showing a method for forming a carbon nano-tube field-effect transistor according to a third embodiment of the present invention. In FIG. 3A, a substrate 300 is provided, and a patterned conductive layer 310 is formed on the substrate 300. In the present embodiment, the substrate 300 can be a glass substrate, a flexible substrate or a conductive substrate with an insulating layer thereon. The patterned conductive layer 310 comprises metal, poly-silicon, conductive polymer or combination thereof. In general, the patterned conductive layer 310 is used as the bottom gate of a thin-film transistor.

In FIG. 3B, a dielectric layer 320 is then formed to cover the conductive layer 310 and the substrate 300. In the present embodiment, the dielectric layer 320 comprises oxide, nitride, insulating polymer or the combination thereof.

Then, a carbon nano-tube layer 340 between a pair of islands 335 comprising a catalyst is formed on the dielectric layer 320, and as shown in FIG. 3C. In the present embodiment, the catalyst comprises one material selected from a group including ferrum (Fe), cobalt (Co), nickel (Ni), other transitional elements and combination thereof, and the carbon nano-tube layer 340 is formed by CVD. In general, part of the carbon nano-tube layer 340 is used as the channel layer.

In FIG. 3D, a pair of electrodes 330 are formed on the dielectric layer 320 so as to cover the islands 335 and are electrically coupled to the carbon nano-tube layer 340. In the present embodiment, the electrodes 330 comprise metal, conductive polymer or combination thereof. In general, the electrodes 330 are used as the drain electrode and the source electrode.

A carbon nano-tube field-effect transistor has been completed using the afore-mentioned steps. However, the carbon nano-tube layer 340 usually comprises both metallic carbon nano-tubes and semiconducting carbon nano-tubes. Metallic carbon nano-tubes are not suitable for use in a channel for a field-effect transistor because a channel having metallic carbon nano-tubes may exhibit poor switching characteristics. Therefore, a treatment process is preferably performed on the carbon nano-tube layer 340 so as to convert metallic carbon nano-tubes into semiconducting carbon nano-tubes. In the present embodiment, the treatment process comprises one process selected from a group including a physical treatment process, a chemical treatment process and combination thereof. Preferably, the physical treatment process comprises a step of bombarding the carbon nano-tube layer with micro particles 350, as shown in FIG. 3E.

Preferably, the micro particles 350 are provided using one source selected from a group including a plasma generator, an ion implanter, an ion shower, and an electron gun. With the bombardment of the micro particles 350, the effective chirality of the carbon nano-tubes is altered, which convert the metallic carbon nano-tubes into semiconducting carbon nano-tubes. Alternatively, the physical treatment process comprises a step of inducing eddy currents in the carbon nano-tube layer 340 so as to burn up the metallic carbon nano-tubes and increase the semiconducting-to-metallic ratio. Preferably, the chemical treatment process comprises a step of providing reactive ions to react with the carbon nano-tube layer.

Preferably, in the present embodiment, the method further comprises a step of forming an organic semiconductor layer 360 covering the carbon nano-tube layer 340 and the pair of electrodes 330 after the treatment process so as to form an organic field-effect transistor, as shown in FIG. 3F. In the present embodiment, the organic semiconductor layer 360 is a polymeric material formed by spin coating, ink-jet printing, screen printing, thermal transfer printing or imprinting or a small molecular material formed by evaporation.

Preferably, a passivation layer (not shown) can be further provided on the organic semiconductor layer 360 so as to prevent the organic semiconductor layer 360 from moisture or oxide. The passivation layer can be implemented using oxide, nitride, insulating polymer or the combination thereof.

### Fourth Embodiment

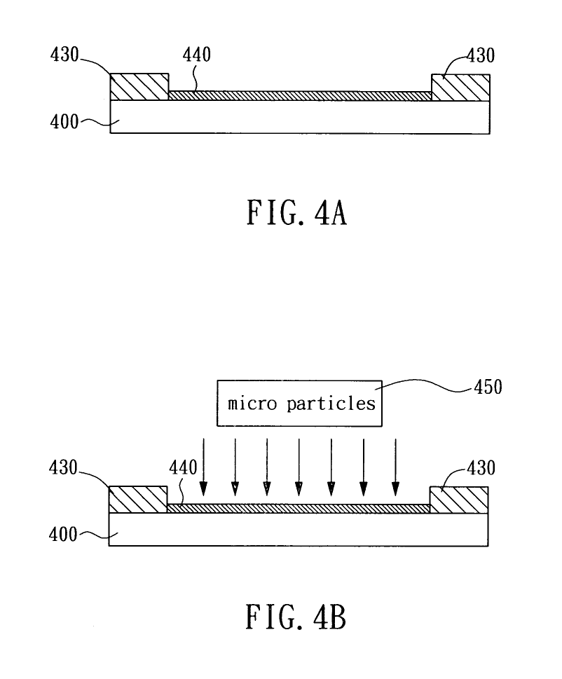

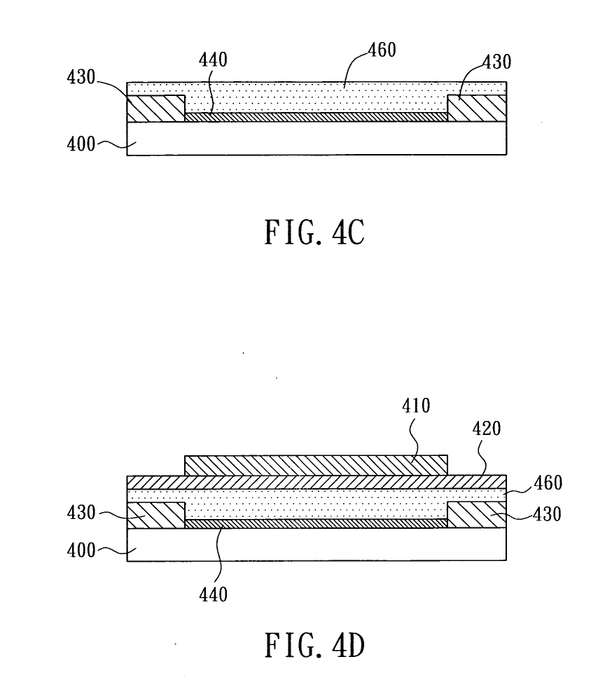

FIG. 4A to FIG. 4D are cross-sectional views showing a method for forming a carbon nano-tube field-effect transistor according to a fourth embodiment of the present invention. In FIG. 4A, a substrate 400 is provided, and a carbon nano-tube layer 440 between a pair of electrodes 430 is formed on the substrate 400. In the present embodiment, the substrate 400 can be a glass substrate, a flexible substrate or a conductive substrate with an insulating layer thereon. The electrodes 430 comprise metal, conductive polymer or combination thereof. The carbon nano-tube layer 440 is formed using spin coating, ink-jet printing, screen-printing, thermal transfer printing or imprinting. In general, the electrodes 430 are used as the drain electrode and the source electrode. Part of the carbon nano-tube layer 440 is used as the channel layer.

However, the carbon nano-tube layer 440 usually comprises both metallic carbon nano-tubes and semiconducting carbon nano-tubes. Metallic carbon nano-tubes are not suitable for use in a channel for a field-effect transistor because a channel having metallic carbon nano-tubes may exhibit poor switching characteristics. Therefore, a treatment process is preferably performed on the carbon nano-tube layer 440 so as to convert metallic carbon nano-tubes into semiconducting carbon nano-tubes. In the present embodiment, the treatment process comprises one process selected from a group including a physical treatment process, a chemical treatment process and combination thereof. Preferably, the physical treatment process comprises a step of bombarding the carbon nano-tube layer with micro particles 450, as shown in FIG. 4B.

Preferably, the micro particles 450 are provided using one source selected from a group including a plasma generator, an ion implanter, an ion shower, and an electron gun. With the bombardment of the micro particles 450, the effective chirality of the carbon nano-tubes is altered, which convert the metallic carbon nano-tubes into semiconducting carbon nano-tubes. Alternatively, the physical treatment process comprises a step of inducing eddy currents in the carbon nano-tube layer 440 so as to burn up the metallic carbon nano-tubes and increase the semiconducting-to-metallic ratio. Preferably, the chemical treatment process comprises a step of providing reactive ions to react with the carbon nano-tube layer.

After the treatment process, an organic semiconductor layer 460 is formed to cover the carbon nano-tube layer 440 and the pair of electrodes 430, as shown in FIG. 4C. In the present embodiment, the organic semiconductor layer 460 is a polymeric material formed by spin coating, ink-jet printing, screen printing, thermal transfer printing or imprinting or a small molecular material formed by evaporation.

Finally, a dielectric layer 420 is formed on the organic semiconductor layer 460 and a patterned conductive layer 410 is formed on the dielectric layer 420 so as to form an organic field-effect transistor, as shown in FIG. 4D. In the present embodiment, the dielectric layer 420 comprises oxide, nitride, insulating polymer or the combination thereof. The patterned conductive layer 410 comprises metal, poly-silicon, conductive polymer or combination thereof. In general, the patterned conductive layer 410 is used as the top gate of a thin-film transistor.

Alternatively, in the present embodiment, right after the treatment process, the dielectric layer 420 is formed to cover the carbon nano-tube layer 440 and the electrodes 430, and then the patterned conductive layer 410 is formed on the dielectric layer 420 without forming the organic semiconductor layer 460.

### Fifth Embodiment

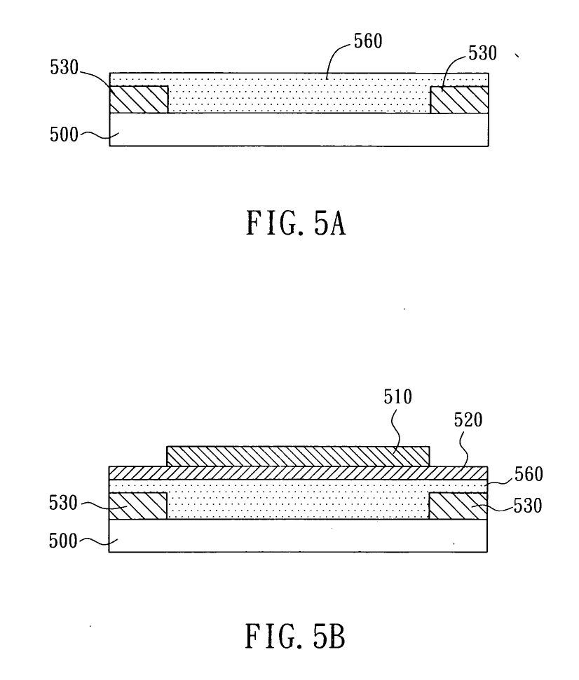

FIG. 5A to FIG. 5B are cross-sectional views showing a method for forming a carbon nano-tube field-effect transistor according to a fifth embodiment of the present invention. In FIG. 5A, a substrate 500 is provided, and an organic semiconductor layer 560 between a pair of electrodes 530 is formed on the substrate 500, wherein the organic semiconductor layer 560 is doped with a plurality of semiconducting carbon nano-tube particles (not shown) so as to increase the electrical characteristics of an organic CNT field-effect transistor.

In the present embodiment, the substrate 500 can be a glass substrate, a flexible substrate or a conductive substrate with an insulating layer thereon. In the present embodiment, the electrodes 530 comprise metal, conductive polymer or combination thereof. In general, the electrodes 530 are used as the drain electrode and the source electrode. Part of the organic semiconductor layer 560 is used as the channel layer. In the present embodiment, the organic semiconductor layer 560 is a polymeric material formed by spin coating, ink-jet printing, screen printing, thermal transfer printing or imprinting or a small molecular material formed by evaporation.

In FIG. 5B, a dielectric layer 520 is then formed on said organic semiconductor layer 560 and a patterned conductive layer 510 is formed on the dielectric layer 520. In the present embodiment, the dielectric layer 520 comprises oxide, nitride, insulating polymer or the combination thereof. In the present invention, the patterned conductive layer 510 comprises metal, poly-silicon, conductive polymer or combination thereof. In general, the patterned conductive layer 510 is used as the bottom gate of a thin-film transistor.

### Sixth Embodiment

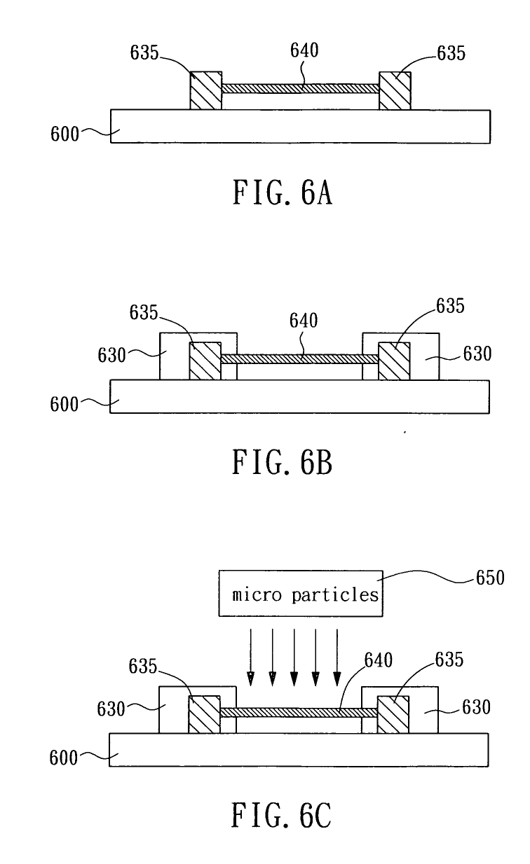

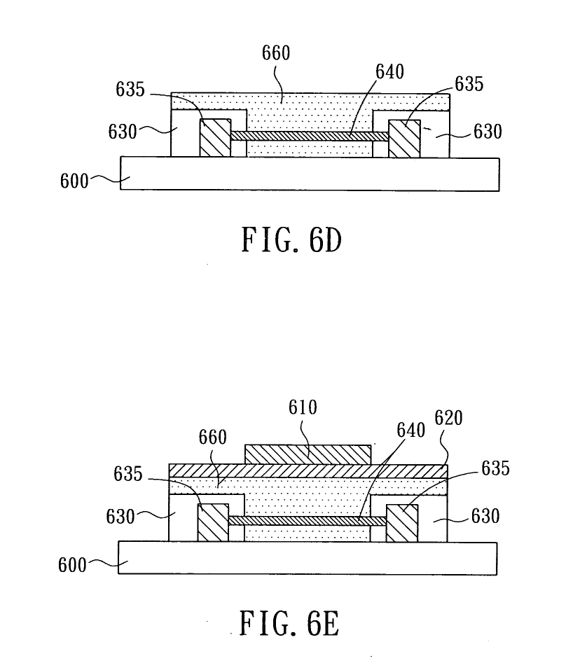

FIG. 6A to FIG. 6E are cross-sectional views showing a method for forming a carbon nano-tube field-effect transistor according to a sixth embodiment of the present invention. In FIG. 6A, a substrate 600 is provided, and a carbon nano-tube layer 640 between a pair of islands 635 comprising a catalyst is formed on the substrate 600. In the present embodiment, the substrate 600 can be a glass substrate, a flexible substrate or a conductive substrate with an insulating layer thereon. The catalyst comprises one material selected from a group including ferrum (Fe), cobalt (Co), nickel (Ni), other transitional elements and combination thereof, and the carbon nano-tube layer 640 is formed by CVD. In general, part of the carbon nano-tube layer 640 is used as the channel layer.

In FIG. 6B, a pair of electrodes 630 are formed on the substrate 600 to cover the islands 635 and electrically coupled to the carbon nano-tube layer 640. In the present embodiment, the electrodes 630 comprise metal, conductive polymer or combination thereof. In general, the electrodes 630 are used as the drain electrode and the source electrode.

However, the carbon nano-tube layer 640 usually comprises both metallic carbon nano-tubes and semiconducting carbon nano-tubes. Metallic carbon nano-tubes are not suitable for use in a channel for a field-effect transistor because a channel having metallic carbon nano-tubes may exhibit poor switching characteristics. Therefore, a treatment process is preferably performed on the carbon nano-tube layer 640 so as to convert metallic carbon nano-tubes into semiconducting carbon nano-tubes. In the present embodiment, the treatment process comprises one process selected from a group including a physical treatment process, a chemical treatment process and combination thereof Preferably, the physical treatment process comprises a step of bombarding the carbon nano-tube layer with micro particles 650, as shown in FIG. 6C.

Preferably, the micro particles 650 are provided using one source selected from a group including a plasma generator, an ion implanter, an ion shower, and an electron gun. With the bombardment of the micro particles 650, the effective chirality of the carbon nano-tubes is altered, which convert the metallic carbon nano-tubes into semiconducting carbon-nano-tubes. Alternatively, the physical treatment process comprises a step of inducing eddy currents in the carbon nano-tube layer 640 so as to burn up the metallic carbon nano-tubes and increase the semiconducting-to-metallic ratio. Preferably, the chemical treatment process comprises a step of providing reactive ions to react with the carbon nano-tube layer.

After the treatment process, an organic semiconductor layer 660 is formed to cover the carbon nano-tube layer 640 and the pair of electrodes 630, as shown in FIG. 6D. In the present embodiment, the organic semiconductor layer 660 is a polymeric material formed by spin coating, ink-jet printing, screen printing, thermal transfer printing or imprinting or a small molecular material formed by evaporation.

Finally, a dielectric layer 620 is formed on the organic semiconductor layer 660 and a patterned conductive layer 610 is formed on the dielectric layer 620 so as to form an organic field-effect transistor, as shown in FIG. 6E. In the present embodiment, the dielectric layer 620 comprises oxide, nitride, insulating polymer or the combination thereof The patterned conductive layer 610 comprises metal, poly-silicon, conductive polymer or combination thereof. In general, the patterned conductive layer 610 is used as the top gate of a thin-film transistor.

Alternatively, in the present embodiment, right after the treatment process, the dielectric layer 620 is formed to cover the carbon nano-tube layer 640 and the electrodes 630, and then the patterned conductive layer 610 is formed on the dielectric layer 620 so as to form an organic field-effect transistor without forming the organic semiconductor layer 660.

According to the above discussion, it is apparent that the present invention discloses a method for manufacturing a carbon nano-tube field-effect transistor using a treatment process after carbon nano-tubes are deposited so as to convert metallic carbon nano-tubes into semiconducting carbon nano-tubes. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

The invention claimed is:

1. A method for manufacturing a carbon nano-tube field-effect transistor (CNT-FET), comprising steps of:
forming a patterned conductive layer on a substrate;
forming a dielectric layer covering said conductive layer and said substrate;
forming a carbon nano-tube layer between a pair of electrodes on said dielectric layer; and
performing a treatment process on said carbon nano-tube layer so that said carbon nano-tube layer is semiconducting.

2. The method as recited in claim 1, further comprising a step of:
forming an organic semiconductor layer covering said carbon nano-tube layer and said pair of electrodes after said treatment process.

3. The method as recited in claim 1, wherein said treatment process comprises at least one process of a physical treatment process, a chemical treatment process, and combination thereof.

4. The method as recited in claim 3, wherein said physical treatment process comprises a step of:
bombarding said carbon nano-tube layer with micro particles.

5. The method as recited in claim 3, wherein said physical treatment process comprises a step of:
inducing eddy currents in said carbon nano-tube layer.

6. The method as recited in claim 4, wherein said micro particles are provided using at least one source of a plasma generator, an ion implanter, an ion shower, and an electron gun.

7. The method as recited in claim 3, wherein said chemical treatment process comprises a step of:
providing reactive ions to react with said carbon nano-tube layer.

8. The method as recited in claim 2, wherein said organic semiconductor layer is a polymeric material formed by spin coating, ink-jet printing, screen printing, thermal transfer printing or imprinting.

9. The method as recited in claim 2, wherein said organic semiconductor layer is a small molecular material formed by evaporation.

10. A method for manufacturing a carbon nano-tube field-effect transistor (CNT-FET), comprising steps of:
forming a patterned conductive layer on a substrate;
forming a dielectric layer covering said conductive layer and said substrate; and
forming an organic semiconductor layer between a pair of electrodes on said dielectric layer;
wherein said organic semiconductor layer is doped with a plurality of semiconducting carbon nano-tube particles.

11. The method as recited in claim 10, wherein said organic semiconductor layer is a polymeric material formed by spin coating, ink-jet printing, screen printing, thermal transfer printing or imprinting.

12. The method as recited in claim 10, wherein said organic semiconductor layer is a small molecular material formed by evaporation.

13. A method for manufacturing a carbon nano-tube field-effect transistor, comprising steps of:
forming a patterned conductive layer on a substrate;
forming a dielectric layer covering said conductive layer and said substrate;
forming a carbon nano-tube layer between a pair of islands on said dielectric layer, said pair of islands comprising a catalyst;
forming a pair of electrodes on said dielectric layer, said pair of electrodes covering said islands and being electrically coupled to said carbon nano-tube layer; and
performing a treatment process on said carbon nano-tube layer so that said carbon nano-tube layer is semiconducting.

14. The method as recited in claim 13, further comprising a step of:
forming an organic semiconductor layer covering said carbon nano-tube layer and said pair of electrodes after said treatment process.

15. The method as recited in claim 13, wherein said catalyst comprises at least one material of ferrum (Fe), cobalt (Co), nickel (Ni), other transitional elements and combination thereof.

16. The method as recited in claim 13, wherein said treatment process comprises at least one process of a physical treatment process, a chemical treatment process and combination thereof.

17. The method as recited in claim 16, wherein said physical treatment process comprises a step of:
bombarding said carbon nano-tube layer with micro particles.

18. The method as recited in claim 16, wherein said physical treatment process comprises a step of:
inducing eddy currents in said carbon nano-tube layer.

19. The method as recited in claim 17, wherein said micro particles are provided using at least one source of a plasma generator, an ion implanter, an ion shower, and an electron gun.

20. The method as recited in claim 16, wherein said chemical treatment process comprises a step of:
providing reactive ions to react with said carbon nano-tube layer.

21. The method as recited in claim 14, wherein said organic semiconductor layer is a polymeric material formed by spin coating, ink-jet printing, screen printing, thermal transfer printing or imprinting.

22. The method as recited in claim 14, wherein said organic semiconductor layer is a small molecular material formed by evaporation.

23. A method for manufacturing a carbon nano-tube field-effect transistor, comprising steps of:
forming a carbon nano-tube layer between a pair of electrodes on a substrate;
performing a treatment process on said carbon nano-tube layer so that said carbon nano-tube layer is semiconducting;
forming a dielectric layer on said carbon nano-tube layer and said pair of electrodes; and
forming a patterned conductive layer.

24. The method as recited in claim 23, further comprising a step of:
forming an organic semiconductor layer covering said carbon nano-tube layer and said pair of electrodes after said treatment process.

25. The method as recited in claim 23, wherein said treatment process comprises at least one process of a physical treatment process, a chemical treatment process and combination thereof.

26. The method as recited in claim 25, wherein said physical treatment process comprises a step of:
bombarding said carbon nano-tube layer with micro particles.

27. The method as recited in claim 25, wherein said physical treatment process comprises a step of:
inducing eddy currents in said carbon nano-tube layer.

28. The method as recited in claim 26, wherein said micro particles are provided using at least one source of a plasma generator, an ion implanter, an ion shower, and an electron gun.

29. The method as recited in claim 25, wherein said chemical treatment process comprises a step of:
providing reactive ions to react with said carbon nano-tube layer.

30. The method as recited in claim 24, wherein said organic semiconductor layer is a polymeric material formed by spin coating, ink-jet printing, screen printing, thermal transfer printing or imprinting.

31. The method as recited in claim 24, wherein said organic semiconductor layer is a small molecular material formed by evaporation.

32. A method for manufacturing a carbon nano-tube field-effect transistor (CNT-FET), comprising steps of:
forming an organic semiconductor layer between a pair of electrodes on a substrate;
forming a dielectric layer on said organic semiconductor layer; and
forming a patterned conductive layer on said dielectric layer;
wherein said organic semiconductor layer is doped with a plurality of semiconducting carbon nano-tube particles.

33. The method as recited in claim 32, wherein said organic semiconductor layer is a polymeric material formed by spin coating, ink-jet printing, screen printing, thermal transfer printing or imprinting.

34. The method as recited in claim 32, wherein said organic semiconductor layer is a small molecular material formed by evaporation.

35. A method for manufacturing a carbon nano-tube field-effect transistor, comprising steps of:
forming a carbon nano-tube layer between a pair of islands on a substrate, said pair of islands comprising a catalyst;
forming a pair of electrodes on said substrate, said pair of electrodes covering said islands and being electrically coupled to said carbon nano-tube layer;
performing a treatment process on said carbon nano-tube layer so that said carbon nano-tube layer is semiconducting;
forming a dielectric layer on said carbon nano-tube layer and said pair of electrodes; and
forming a patterned conductive layer on said dielectric layer.

36. The method as recited in claim 35, further comprising a step of:
forming an organic semiconductor layer covering said carbon nano-tube layer and said pair of electrodes after said treatment process.

37. The method as recited in claim 35, wherein said catalyst comprises at least one material selected of ferrum (Fe), cobalt (Co), nickel (Ni), other transitional elements and combination thereof.

38. The method as recited in claim 35, wherein said treatment process comprises at least one process of a physical treatment process, a chemical treatment process and combination thereof.

39. The method as recited in claim 38, wherein said physical treatment process comprises a step of:
bombarding said carbon nano-tube layer with micro particles.

40. The method as recited in claim 38, wherein said physical treatment process comprises a step of:
inducing eddy currents in said carbon nano-tube layer.

41. The method as recited in claim 39, wherein said micro particles are provided using at least one source of a plasma generator, an ion implanter, an ion shower, and an electron gun.

42. The method as recited in claim 38, wherein said chemical treatment process comprises a step of:
providing reactive ions to react with said carbon nano-tube layer.

43. The method as recited in claim 36, wherein said organic semiconductor layer is a polymeric material formed by spin coating, ink-jet printing, screen printing, thermal transfer printing or imprinting.

44. The method as recited in claim 36, wherein said organic semiconductor layer is a small molecular material formed by evaporation.
